(19) United States
(12) Patent Application Publication
(10) Pub. No.: US 2025/0284866 A1
(43) Pub. Date: Sep. 11, 2025

(54) SYSTEM AND METHOD FOR PREDICTING FORMATION PROPERTIES

(71) Applicant: Schlumberger Technology Corporation, Sugar Land, TX (US)

(72) Inventors: Volodymyr Puzyrov, Cambridge, MA (US); Lin Liang, Cambridge, MA (US)

(21) Appl. No.: 19/073,172

(22) Filed: Mar. 7, 2025

Related U.S. Application Data
(60) Provisional application No. 63/562,866, filed on Mar. 8, 2024.

(51) Int. Cl. G06F 30/27

(52) U.S. Cl. CPC G06F 30/27

(57) ABSTRACT

A system and method for predicting formation properties is described. For example, a computing device may receive deep directional resistivity (DDR) measurement data from one or more DDR sensors. The computing device may apply a formation property prediction model to the DDR measurement data, the formation property prediction model pretrained to identify predicted formation parameters based on input DDR data, formation properties of the input DDR data, and tool parameters. The computing device may receive the predicted formation parameters for a subsurface beyond the wellbore in response to applying the formation property prediction model to the DDR measurement data.

### CROSS REFERENCE TO RELATED APPLICATIONS

This application claims priority to and the benefit of U.S. Provisional Patent Application No. 63/562,866, filed on Mar. 8, 2024, which is incorporated herein by reference in its entirety.

### BACKGROUND

Electromagnetic waves are used for evaluating subsurface formation resistivity, which can be used further to determine formation properties for a subsurface beyond the wellbore. The depth of investigation of such methods ranges from several meters away from a wellbore for traditional single-well induction logging tools to more than 30 meters for deep directional resistivity (DDR) tools. Recent advancements in electromagnetic measurement tools and software enhancements provide an opportunity for improved formation evaluation to reduce wellbore position uncertainty, accurately detect formation parameters such as resistivity, anisotropy, dip and azimuth. The collected electromagnetic data are typically interpreted by means of an inversion process to obtain a resistivity distribution map of the formation.

### BRIEF SUMMARY

In some embodiments, a method for predicting formation properties is provided. The method includes receiving deep directional resistivity (DDR) measurement data from one or more DDR sensors. The method further includes applying a formation property prediction model to the DDR measurement data, the formation property prediction model pretrained to identify predicted formation parameters based on input DDR data, formation properties of the input DDR data, and tool parameters. The method further including receiving the predicted formation parameters for a subsurface beyond the wellbore in response to applying the formation property prediction model to the DDR measurement data.

In other embodiments, a system for predicting formation properties is provided. The system includes a deep directional resistivity (DDR) sensor for measuring deep directional resistivity. The system further includes a model generated by a neural network for identifying predicted formation parameters based on a DDR measurement data measured by the DDR sensor and inputted to the neural network without calculating inversion.

In yet other embodiments, a system including a computing device having a processor and a computer memory including instructions that, when executed by the computing device, cause the computing device to carry out operations is provided. The system including receiving deep directional resistivity (DDR) measurement data from one or more DDR sensors. The system further including applying a formation property prediction model to the DDR measurement data, the formation property prediction model pretrained to identify predicted formation parameters based on input DDR data, formation properties of the input DDR data, and tool parameters. The system further including receiving the predicted formation parameters for a subsurface beyond the wellbore in response to applying the formation property prediction model to the DDR measurement data.

This summary is provided to introduce a selection of concepts that are further described below in the detailed description. This summary is not intended to identify key or essential features of the claimed subject matter, nor is it intended to be used as an aid in limiting the scope of the claimed subject matter.

Additional features and advantages of embodiments of the disclosure will be set forth in the description which follows, and in part will be obvious from the description, or may be learned by the practice of such embodiments. The features and advantages of such embodiments may be realized and obtained by means of the instruments and combinations particularly pointed out in the appended claims. These and other features will become more fully apparent from the following description and appended claims, or may be learned by the practice of such embodiments as set forth hereinafter.

### BRIEF DESCRIPTION OF DRAWINGS

In order to describe the manner in which the above-recited and other features of the disclosure can be obtained, a more particular description will be rendered by reference to specific implementations thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example implementations, the implementations will be described and explained with additional specificity and detail through the use of the accompanying drawings in which:

FIG. 1 shows an example representation of a drilling system for drilling an earth formation to create a wellbore according to some implementations.

FIG. 2 shows an example representation of a formation properties prediction system for drilling an earth formation according to some implementations.

FIG. 3 shows an example representation of acquiring DDR measurement data, according to some implementations.

FIG. 4 shows an example representation of training a neural network to predict formation properties, according to some implementations.

FIG. 5 shows an example representation of resistivity profile generated with a formation property prediction model, according to some implementations.

FIG. 6 illustrates a flowchart of a method for predicting formation properties, according to an embodiment.

FIG. 7 illustrates an example of such a computing system, in accordance with some embodiments.

### DETAILED DESCRIPTION

This disclosure generally relates to a formation properties prediction system and method. Deep directional resistivity (DDR) measurements are commonly used for geosteering and reservoir mapping purposes. DDR sensors are typically located in a bottomhole assembly (BHA) near a bit. The DDR sensors measure directional resistivity at the subsurface and provide the measurements for a computing system to predict formation properties, such as resistivity, an anisotropy, a dip and azimuth of the formation relative to the wellbore. Traditionally, the DDR measurements are provided to stochastic or gradient-based inversion algorithms to predict formation properties. These inversion algorithms require numerous simulations to obtain resistivity image that aligns with the downhole measurements, thus leading to high computational cost and slow delivery. Another disadvantage of these traditional inversion algorithms is that they rely on deterministic optimization methods, such as a nonlinear conjugate gradient or Gauss-Newton, and thus may get stuck in iterating a local minimum which could be below the threshold, but not the optimal solution. One of the aims on the formation property prediction system, as further described below, is to fully replace the inversion process when predicting formation properties.

One possible advantage of the formation properties prediction system, as further discussed below, is that the DDR measurements can be processed quickly and with very little computational cost. This may be achieved by training a neural network with input DDR data and their respective formation properties which have been calculated with inversion algorithms offline. By utilizing the formation property prediction model that has been pretrained with the input DDR data and their respective formation properties, the formation properties prediction system is able to process the received DDR measurements faster than with the traditional methods and with less computational cost. In other words, the formation property prediction model enables a quick prediction of formation properties without using traditional inversion algorithms to calculate the inversion. Real-time, or near real-time formation property predictions may allow the operator, downhole drilling system, automated drilling system, or other part of the drilling system to make more informed decisions, including real-time or near real-time adjustments to various drilling parameters, including adjustments to the trajectory of the directional drilling tool.

Another possible advantage of the formation properties prediction system is that an uncertainty of the predictions may be provided with quantitative metrics of uncertainty. This may be achieved by utilizing Monte Carlo dropout technique to quantify epistemic uncertainty in the outputs provided by a formation property prediction model. For example, the Monte Carlo dropout technique may facilitate the statistical analysis of the impact of random dropout of various nodes in a formation property prediction model. This may provide an indication of the uncertainty of the formation property model generated by the neural network. In another example, the Monte Carlo dropout technique can be used to indicate the uncertainty in the formation property predictions generated by the formation property prediction model.

As illustrated in the foregoing discussion, this disclosure utilizes a variety of terms to describe the features and advantages of one or more implementations described. As an example, the term “deep directional resistivity” (“DDR”) refers to resistivity measurements that are commonly used for geosteering and reservoir mapping purposes. Resistivity is the measurement of the resistance of a formation to the transmission of an electromagnetic current. Resistivity measurements may be related to the composition of a geological formation, with various fluids and other materials having different resistivity patterns. DDR systems may measure resistivity at distances of 30 m or more from the DDR sensor. DDR sensors are typically located in a bottomhole assembly (BHA) near a bit. The DDR sensors measure directional resistivity at subsurface and provide the measurements for a computing system to predict formation properties, such as resistivity, an anisotropy, a dip and azimuth of the formation relative to the wellbore.

As an example, the term “machine learning” refers to algorithms that generate data-driven predictions or decisions from known input data by modeling high-level abstractions. Examples of machine-learning models include computer representations that are tunable (e.g., trainable) based on inputs to approximate unknown functions. For instance, a machine-learning model includes a model that utilizes algorithms to learn from, and make predictions on, known data by analyzing the known data to learn to generate outputs that reflect patterns and attributes of the known data. For example, machine-learning models include latent Dirichlet allocation (LDA), multi-arm bandit models, linear regression models, logistical regression models, random forest models, support vector machines (SVMs), neural networks (convolutional neural networks, recurrent neural networks such as LSTMs, graph neural networks, etc.), or decision tree models. For example, the formation prediction model may be a lightweight machine learning model and/or algorithm.

As another example, the term “neural network” refers to a machine learning model comprising interconnected artificial neurons that communicate and learn to approximate complex functions, generating outputs based on multiple inputs provided to the model. For instance, a neural network includes an algorithm (or set of algorithms) that employs deep learning techniques and utilizes training data to adjust the parameters of the network and model high-level abstractions in data. Various types of neural networks exist, such as convolutional neural networks (CNNs), transformer networks, feedforward neural network (FNNs), residual learning neural networks, recurrent neural networks (RNNs), generative neural networks, generative adversarial networks (GANs), and single-shot detection (SSD) networks.

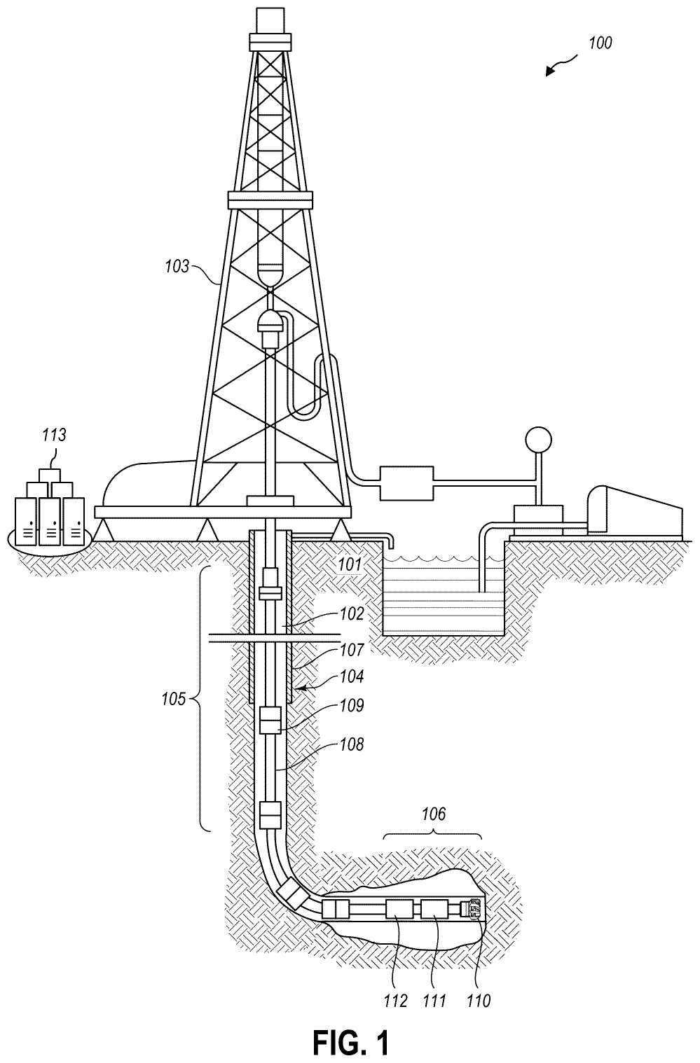

FIG. 1 shows an example representation of a drilling system for drilling an earth formation to create a wellbore according to some implementations. In particular, FIG. 1 provides additional context regarding a formation properties prediction system. To illustrate, FIG. 1 shows an example of a drilling system 100 for drilling an earth formation 101 to form a wellbore 102. The drilling system 100 (e.g., a downhole drilling system) includes a drill rig 103 used to turn a drilling tool assembly 104 that extends downward into the wellbore 102. The drilling tool assembly 104 may include a drill string 105, a bottomhole assembly (“BHA 106”), and a bit 110 attached to the downhole end of the drill string 105.

The drill string 105 may include several joints of drill pipe 108 connected end-to-end through tool joints 109. The drill string 105 transmits drilling fluid through a central bore and transmits rotational power from the drill rig 103 to the BHA 106. In some embodiments, the drill string 105 may further include additional components such as subs, pup joints, etc. The drill pipe 108 provides a hydraulic passage through which drilling fluid is pumped from the surface. The drilling fluid discharges through nozzles, jets, or other openings in the bit 110 for purposes such as cooling the bit 110 and its cutting structures, lifting cuttings out of the wellbore 102 during drilling, controlling fluid influx in the well, maintaining wellbore integrity, and other functions.

The BHA 106 may include the bit 110 or other components. An example BHA 106 may include additional or different components (e.g., coupled between the drill string 105 and the bit 110). Examples of additional BHA components include drill collars, stabilizers, measurement-while-drilling (MWD) tools, logging-while-drilling (LWD) tools, downhole motors, underreamers, section mills, hydraulic disconnects, jars, vibration or damping tools, other components, or combinations of these components.

The BHA 106 may further include a directional tool 111 such as a bent housing motor or a rotary steerable system (RSS). The directional tool 111 may include directional drilling equipment that changes the direction of the bit 110, thereby altering the trajectory of the wellbore 102. In some cases, at least a portion of the directional tool 111 may maintain a geostationary position relative to an absolute reference frame, such as gravity, magnetic north, or true north. Using measurements obtained from this geostationary position, the directional tool 111 may locate the bit 110, modify its course, and guide the directional tool 111 along a projected trajectory. For instance, the BHA 106 (including the directional tool 111) is shown transitioning from vertical to horizontal drilling, causing the bit 110 to move along a horizontal path away from the drill rig 103.

In general, the drilling system 100 may include additional or different drilling components and accessories including special valves (e.g., blowout preventers and safety valves). Additional components within the drilling system 100 may be categorized as part of the drilling tool assembly 104, the drill string 105, or part of the BHA 106 depending on their specific locations within the drilling system 100.

The bit 110 in the BHA 106 may be any type of bit suitable for degrading downhole materials such as the earth formation 101. Examples of drill bits used for drilling earth formations include fixed-cutter or drag bits, roller cone bits, and combinations thereof. In other embodiments, the bit 110 may be a mill used for removing metal, composite, elastomer, or other downhole materials, or combinations thereof. For instance, the bit 110 may be used with a whipstock to mill into the casing 107 lining the wellbore 102. The bit 110 may also be a junk mill used to mill away tools, plugs, cement, or other materials within the wellbore 102, or combinations thereof. Swarf or other cuttings formed by the use of a mill may be lifted to the surface or allowed to fall downhole. In still other embodiments, the bit 110 may include a reamer. For instance, an underreamer may be used in connection with a drill bit, and the drill bit may bore into the formation while the underreamer enlarges the size of the bore.

While performing downhole activities, a subsurface structure system may receive information regarding the earth formation 101 based on one or more sets of survey data. For example, the BHA 106 may include downhole tool sensors 112 (e.g., an LWD tool). The downhole tool sensors 112 may collect downhole measurement data about the earth formation 101 including formation pressures and properties. As a specific, non-limiting example, the downhole tool sensors 112 may be resistivity sensors. In some embodiments, the downhole tool sensors 112 may include DDR sensors having a transmitter that transmits electromagnetic waves into the earth formation 101 and a receiver that receives the electromagnetic waves back at the downhole tool sensors 112. For example, downhole measurement data may be collected by transmitting electromagnetic waves away from the downhole tool sensors 112 and detecting the returning electromagnetic waves after they have interacted with the subsurface formation. The received signals (e.g., DDR measurements) may then be analyzed to predict formation properties, such as resistivity and directional information. In some examples, the downhole tool sensors 112 may further include location detection sensors that may detect the current wellbore location and trajectory, such as the location and trajectory of the bit 110 and/or the BHA 106 and store it in a wellbore data log. In some embodiments, the downhole measurement data and/or the predicted formation properties may be delivered to a surface processing facility 113 for further processing. For example, downhole measurement data may be transmitted to the surface using mud pulse telemetry, acoustic transmission through the drill string 105, electric transmission through a wired pipe or other wired connection, wireless electromagnetic transmission, and so forth.

In various implementations, the wellbore 102 follows a wellbore drilling plan. A wellbore drilling plan maps out a projected trajectory for the wellbore 102 to follow. The wellbore drilling plan may include various control points for checking the current location of the BHA 106 and/or bit 110 in comparison to the wellbore drilling plan and/or formation properties detected via the downhole tool sensors 112. Changes in the resistivity information measured by the downhole tool sensors 112 may prompt the system to make changes in the wellbore drilling plan.

As described in this disclosure, the formation properties prediction system provides a framework to quickly react to changed formation properties. For instance, in various implementations, the formation properties prediction system is able to predict formation properties much faster than traditional systems. For example, the formation properties prediction system may include a formation property prediction model at the BHA 106. The formation property prediction model may analyze received DDR measurements and identify formation properties without performing a processor and time-intensive inversion. The formation property prediction model may be generated by a neural network pretrained in machine learning techniques to analyze input DDR data, the associated inversions, and the resulting formation properties. As a result, the majority of the processing for the formation properties prediction system may be front-loaded pre-training (e.g., during the inversion technique) or during training of the neural network on previously performed inversions. Such front-loading may be performed before the BHA 106 enters the wellbore 102. In some embodiments, the formation property prediction model may be loaded or updated while the BHA 106 is in the wellbore 102.

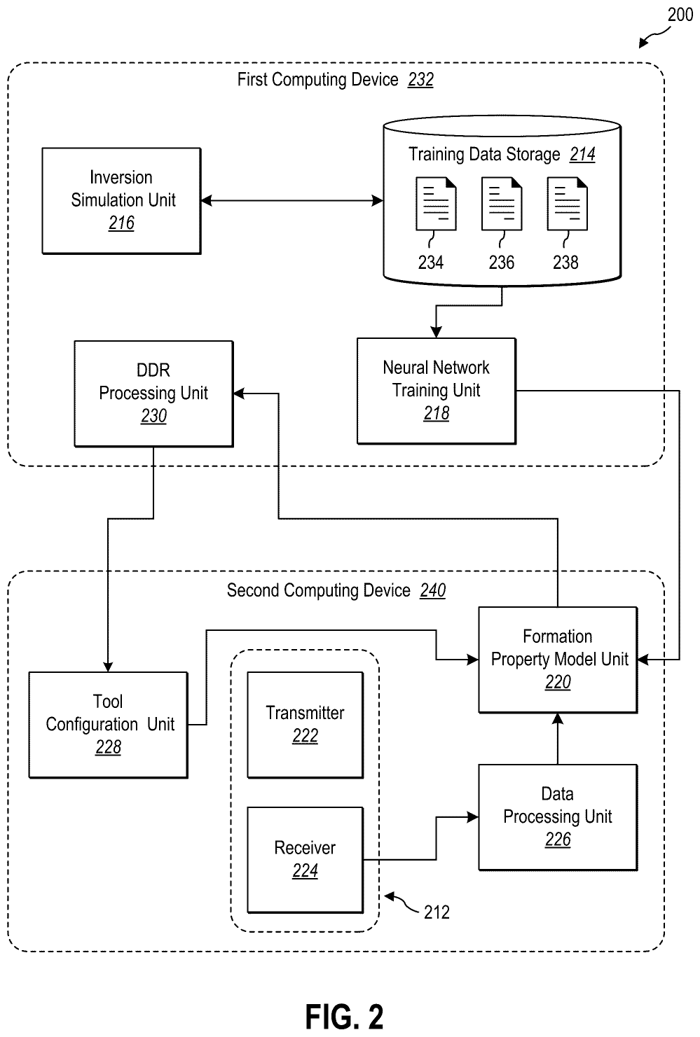

FIG. 2 shows an example representation of a formation properties prediction system 200 for drilling an earth formation according to some implementations. The formation properties prediction system 200 includes a first computing device 232 and a second computing device 240. In some embodiments, the first computing device 232 may be located at a surface location. For example, the first computing device 232 may be located in a surface processing facility 113, as described in FIG. 1. In some examples, the first computing device 232 may be located at a remote computing device, such as a cloud computing device, a computing device located at a location away from the wellbore (such as a corporate or regional office), or other location.

The second computing device 240 may be located at the wellbore. For example, the second computing device 240 may be located at the surface of the wellbore. In some examples, the second computing device 240 may be located downhole, such as at the BHA 106, at an LWA tool, or other processing resource downhole. The first computing device 232 may have more processing power than the second computing device 240. For example, the first computing device 232 may be a field computing device and/or device located on a downhole tool. Such computing systems may have limited processing capacity. For example, power and/or size constraints may reduce the processing capacity of the second computing device 240. While the first computing device 232 and the second computing device 240 are discussed as different computing devices, it should be understood that the techniques of the present disclosure may be applied to scenarios in which the first computing device 232 and the second computing device 240 are the same computing device. For example, both the first computing device 232 and the second computing device 240 may be located at the surface processing facility 113.

The first computing device 232 includes a training data storage 214. The training data storage 214 may store input DDR data 234. The input DDR data 234 may include historical DDR measurement data, simulated DDR data, or a combination thereof. In some embodiments, the training data storage 214 further stores tool parameters 236 that correspond to the input DDR data 234. In some embodiments, the tool parameters 236 may include BHA assembly information, BHA trajectory, DDR sensor configuration information, or a combination thereof. For example, the BHA assembly information may include information about the bit type and size, relative distance between the bit and the DDR sensors, or a combination thereof. The BHA trajectory may include the azimuth and inclination of the BHA, including the relative angle of the BHA in relation to horizontal or vertical plane. The DDR sensor configuration information may include distance between the transmitter and the receiver, an angle between the transmitter 222 and the receiver 224, or a combination thereof.

The formation properties prediction system 200 further includes an inversion simulation unit 216. The inversion simulation unit 216 is configured to use inversion algorithms to calculate formation properties for the input DDR data 234. For example, the inversion simulation unit 216 may receive DDR data 234 from training data storage 214. In some embodiments, the formation properties include resistivity, anisotropy, dip of the formation, azimuth, or a combination thereof. Once the inversion simulation unit 216 has calculated the formation properties for the input DDR data 234, the inversion simulation unit 216 provides the results to the training data storage 214, and the training data storage 214 stores the formation properties data 238.

The formation properties prediction system 200 further includes a neural network training unit 218. The neural network training unit 218 refers to a machine learning model comprising interconnected artificial neurons that communicate and learn to approximate complex functions based on the multiple inputs and outputs provided to the model. In one embodiment, a set of input DDR data 234 with their corresponding tool parameters 236 and formation properties data 238 are provided to the neural network training unit 218. The input DDR data 234 and the tool parameters 236 represent the inputs and the formation properties data 238 represents the outputs. A plurality of these sets are provided to the neural network training unit 218 to learn the complex functions between the inputs and outputs. The neural network training unit 218 uses the data to generate a formation property prediction model configured to predict the formation properties (i.e., the outputs) based on received inputs (i.e., the DDR measurement data).

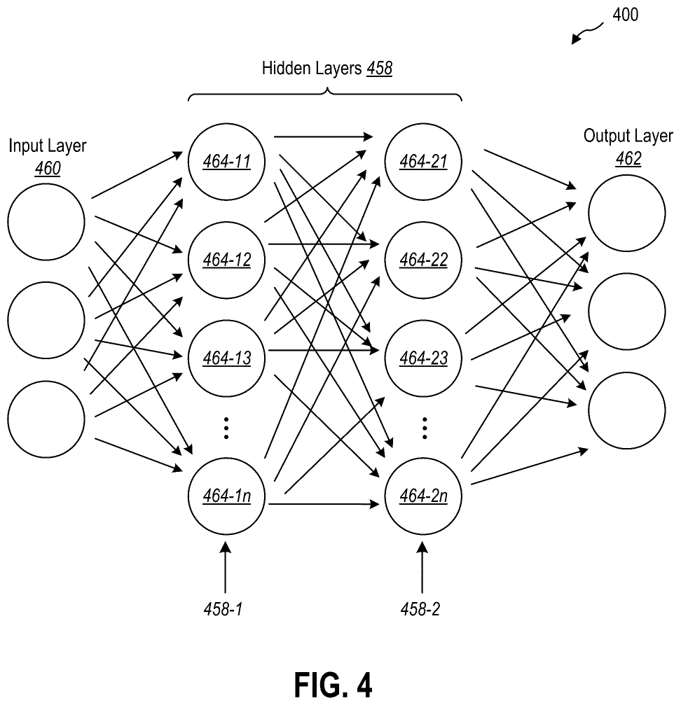

In some embodiments, the formation property model is a pixel based model that provides formation property predictions for each pixel in a one-dimensional formation resistivity image. For example, the formation property model is developed by a training data that is pixel based training data. In some embodiments, the formation property model is a layer based model. Instead of modeling resistivity for each pixel in a one-dimensional formation resistivity image, the layer based model predicts at which depth different layer boundaries are. In other words, the predicted formation parameters are calculated for layer boundaries with associated resistivities. Additional details of training the formation property model and the different model types are provided in connection with FIG. 4.

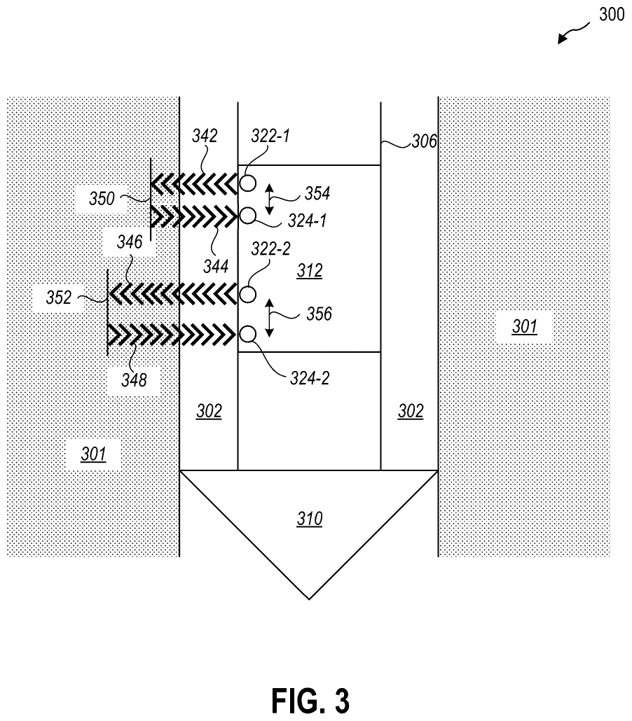

The second computing device 240 includes a formation property prediction model unit 220. The formation property prediction model unit 220 is configured to receive and store the formation property prediction model which is outputted from the neural network training unit 218. The formation property prediction model unit 220 is configured to utilize the received model to predict formation properties based on a received DDR measurement data. As previously discussed in connection with FIG. 1, the BHA 106 may include downhole tool sensors 112, such as the DDR sensor 212 in FIG. 2. The DDR sensor 212 includes one or more transmitter(s) 222 and one or more receiver(s) 224. The one or more transmitter(s) 222 are configured to transmit electromagnetic waves into the surrounding formations. These waves are generated by antennas, and they can be operated at multiple frequencies to penetrate different depths. In some embodiments, the frequency range is between 2 kilo Hertz (kHz) and 72 kHz. In some embodiments, the frequency range is below 2 kHz. In some embodiments, the frequency range is above 72 kHz. In some embodiments, plurality of different frequency ranges are used to measure resistivity at different depths beyond the wellbore subsurface, as further discussed in connection to FIG. 3. In some embodiments, each frequency is measured with plurality of different channels. For example, each frequency could be measured by eight channels providing eight different measurements. In some embodiments each frequency could be measured by more than eight channels. In some embodiments, each frequency could be measured with less than eight channels. In some embodiments, the number of channels used by the DDR sensor is between 10 and 80. For example, the number of channels used may be 48. In some embodiments, the number of channels used by the DDR sensor is more than 80. In some embodiments, the number of channels used by the DDR sensor is less than 10.

The one or more receiver(s) 224 are configured to detect the returning electromagnetic waves after they have interacted with the formation. The DDR sensor 212 provides the received signals to a data processing unit 226. The data processing unit 226 is configured to calculate resistivity and directional information (i.e., the DDR measurement data) from the received electromagnetic signals. This is done by measuring amplitude and phase shift of the received signal and comparing that to the transmitted signal.

The second computing device 240 further includes a tool configuration unit 228. The tool configuration unit 228 may provide tool parameters that correspond to the measured DDR measurement data. In some examples, the tool parameters include a BHA assembly information, BHA trajectory, DDR sensor configuration information, or a combination thereof. For example, the BHA assembly information may include information about the bit type and size, relative distance between the bit and the DDR sensors, or a combination thereof. The BHA trajectory may include the azimuth and inclination of the BHA, including the relative angle of the BHA in relation to horizontal or vertical plane. The DDR sensor configuration information may include distance between the transmitter and the receiver, an angle between the transmitter and the receiver, or a combination thereof.

After the formation property prediction model unit 220 has predicted the formation properties based on the received DDR measurement data received from data processing unit 226 and the tool configuration information received from the tool configuration unit 228, the formation property prediction model unit 220 may provide the information to a DDR processing unit 230. One possible benefit of providing the predicted formation properties to the DDR processing unit 230 instead of providing the DDR measurement information to them is that bandwidth between the first computing device 232 and the second computing device 240 may be saved. In some embodiments, the DDR processing unit is configured to compare the predicted formation properties to wellbore drilling plans to detect if the wellbore drilling plans need to be adjusted based on predicted changes in the formation properties. In some embodiments, if it is determined that a change is required, the DDR processing unit 230 sends an update to the tool configuration unit 228 to implement the adjustments.

In some embodiments, after the formation property model unit 220 has predicted the formation properties, the formation property model unit 220 delivers the predicted formation properties directly to the tool configuration unit 228, and the tool configuration unit 228 automatically adjusts the wellbore drilling plans based on the predicted changes in the formation properties. One possible advantage of providing the predicted formation properties directly to the tool configuration unit 228 is that the information is provided to the tool configuration unit 228 in real-time. In some embodiments, the bandwidth between the first computing device 232 and the second computing device 240 is limited, hence by providing the predicted formation properties directly to the tool configuration unit 228 allows real-time downhole responses.

FIG. 3 shows an example representation of acquiring DDR measurement data, according to some implementations. To illustrate, FIG. 3 shows an example of a drilling system 300 for drilling an earth formation 301 to form a wellbore 302. The drilling system 300 includes a BHA 306 including a DDR sensor 312 and a bit 310. For illustrative purposes the DDR sensor 312 in FIG. 3 is shown to include two transmitters (322-1, 322-2) and two receivers (324-1, 324-2), but it should be understood that a DDR sensor 312 may include any number of transmitters and/or receivers. As shown in FIG. 3, a first transmitter 322-1 may transmit a first electromagnetic signal 342 using a first frequency and a second transmitter 322-2 may transmit a second electromagnetic signal 346 using a second frequency. The first frequency may penetrate to a first depth 350, while the second frequency may penetrate to a second depth 352, the second depth being deeper than the first depth. For example, the first frequency may be higher frequency than the second frequency as lower frequency electromagnetic waves tend to penetrate deeper.

In some embodiments only one transmitter can be used to transmit electromagnetic signals with different frequencies and only one receiver can be used to detect the returning electromagnetic waves after they have interacted with the formation 301. In some embodiments more than two transmitters can be used to transmit electromagnetic signals with different frequencies and more than two receivers can be used to detect the returning electromagnetic waves after they have interacted with the formation 301.

In some embodiments, a first distance 354 between the first transmitter 322-1 and the first receiver 324-1 is stored by a tool configuration unit, such as the tool configuration unit 228 of FIG. 2. Similarly, a second distance 356 between the second transmitter 322-2 and the second receiver 324-2 is stored by the tool configuration unit. These tool configuration information may then be submitted together with the DDR measurement data to the formation property prediction model, such as the formation property model unit 220 of FIG. 2.

For illustrative purposes the transmitter and receiver are shown to generate and receive the electromagnetic signal in horizontal plane. In some embodiments, the transmitter and the receiver may be configured on the DDR sensor 312 in an angle. This angle information may be stored by the tool configuration information and submitted together with the DDR measurement data to the formation property prediction model for formation prediction purposes.

FIG. 4 shows an example representation of training a neural network to predict formation properties, according to some implementations. In particular, the neural network 400 is pretrained to model datasets by learning patterns and relationships within the data. In some embodiments, the neural network 400 includes a plurality of hidden layers 458 between the input layer 460 and the output layer 462. The hidden layers 458 have a plurality of input nodes (e.g., nodes 464), where each of the nodes operates on the received inputs from the previous layer. In a specific example, a first hidden layer 458-1 has a plurality of nodes (464-11 through 464-1n) and each of the nodes performs an operation on each instance from the input layer 460. Each node of the first hidden layer 458-1 provides a new input into each node of the second hidden layer 458-2, which, in turn, performs a new operation on each of those inputs. The nodes of the second hidden layer 458-2 then passes outputs, such as the formation properties, to the output layer 462. The neural network 400 as shown in FIG. 4 has two hidden layers 458, but it should be understood that the neural network may include any number of hidden layers, including tens, hundreds, thousands, or more hidden layers.

In some embodiments, each of the nodes 464 has a linear function and an activation function. The linear function may attempt to optimize or approximate a solution with a line of best fit. The activation function operates as a test to check the validity of the linear function. In some embodiments, the activation function produces a binary output that determines whether the output of the linear function is passed on the next layer of the neural network model. In this way, the system can limit and/or prevent the propagation of poor fits to the data and/or non-convergent solutions.

The neural network model includes an input layer 460 that receives at least one training dataset. In some embodiments, at least one neural network model uses supervised training. In some embodiments, at least one neural network model uses unsupervised training. Unsupervised training can be used to draw inferences and find patterns or associations from the training dataset(s) without known output. In some embodiments, unsupervised learning can identify clusters of similar labels or characteristics for a variety of training instances and allow the neural network system to extrapolate the performance of instances with similar characteristics.

In some embodiments, semi-supervised training can combine benefits from supervised training and unsupervised training. As described herein, the neural network system can identify associated labels or characteristic between instances, which may allow a training dataset with known outputs and a second training dataset including more general input information to be fused. Unsupervised training can allow the machine learning system to cluster the instances from the second training dataset without known outputs and associate the clusters with known outputs from the first training.

The neural network 400 is provided with training data. The training data includes input DDR data, formation properties of the input DDR data, and tool parameters associated with the input DDR data and the formation properties. The input DDR data may include historical DDR measurement data, simulated DDR data, or a combination thereof. In some embodiments, the tool parameters may include BHA assembly information, BHA trajectory, DDR sensor configuration information, or a combination thereof. For example, the BHA assembly information may include information about the bit type and size, relative distance between the bit and the DDR sensors, or a combination thereof. The BHA trajectory may include the azimuth and inclination of the BHA, including the relative angle of the BHA in relation to horizontal or vertical plane. The DDR sensor configuration information may include distance between the transmitter and the receiver, an angle between the transmitter and the receiver, or a combination thereof.

The input DDR data and the tool parameters correspond to the inputs given to the model while the formation properties previously calculated with inversion algorithms are provided as the outputs. The neural network 400 uses the plurality of inputs and the plurality of outputs to detect relationships and correlations between the data to build a formation property model that is capable of predicting formation properties based on new DDR measurements and tool parameters. By using a neural network 400 to predict formation properties, the formation properties prediction system is able to process the received DDR measurement data faster than with the traditional methods and with less computational cost. In other words, the formation property model allows to quickly predict formation properties without using traditional inversion algorithms to calculate the inversion. When formation property predictions can be received quickly, it allows to quickly realign the BHA and/or to modify wellbore drilling plan. In some embodiments, the neural network is pretrained with millions of different input DDR data and their formation properties.

In some embodiments, a single formation property model may predict plurality of different formation properties, such as resistivity, dip, and anisotropy. In some embodiments, a first formation property model predicts resistivity, a second formation property model predicts anisotropy, and a third formation property model predicts dip.

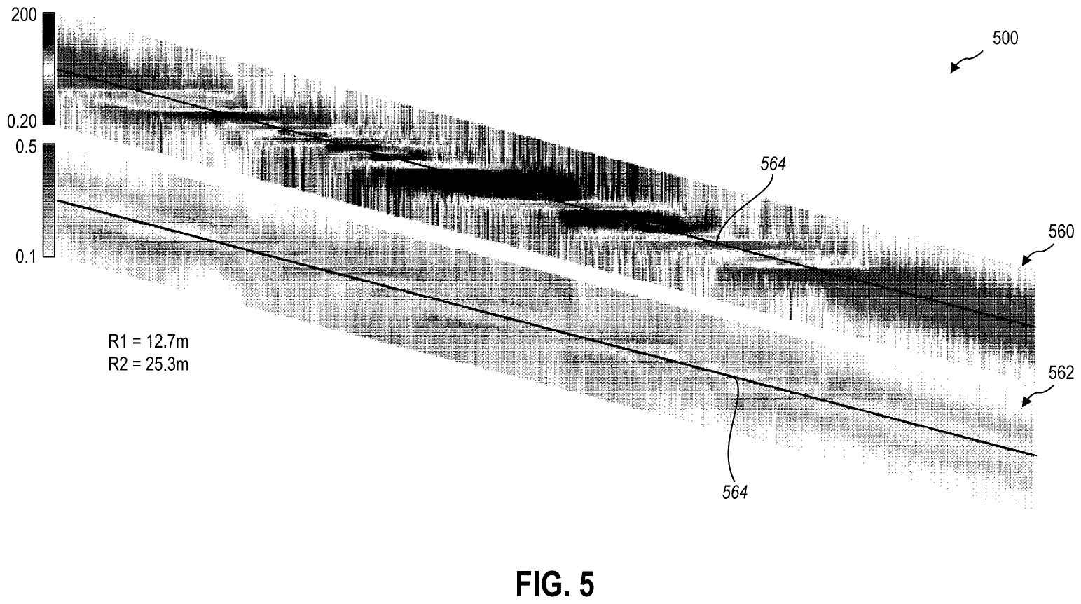

In some embodiments, the formation property model is a pixel based formation property model. In pixel based formation property prediction model, the neural network will predict formation properties for each pixel surrounding the wellbore. An example of a pixel based formation property prediction is provided in FIG. 5. In the pixel based formation property model, the model uses pixel based parameters to define the model, where every point (i.e., pixel) in the one-dimensional, two-dimensional or three-dimensional model includes a resistivity property.

In some embodiments, the formation property prediction model is a layer boundary based model. Instead of predicting resistivity for each and every pixel separately, the model will find boundaries of different resistivity layers, together with associated resistivities for each layer.

In some embodiments, epistemic uncertainty is calculated for the formation property model. This may be achieved by utilizing Monte Carlo dropout technique to quantify uncertainty in the formation property model. For example, the Monte Carlo dropout technique may include dropping one or more nodes (464) from the model. The Monte Carlo simulation may then provide a plurality of predictions based on the one or more nodes that have been dropped. A mean and standard deviation of the formation property model may be calculated based on the plurality of predictions which will provide the quantitative uncertainty of the model. The uncertainty increases the further away from the wellbore, as further shown in connection to FIG. 5.

In some embodiments, the epistemic uncertainty is calculated for the predicted formation properties instead for the model itself. Similarly, as with the Monte Carlo dropout technique used to quantify uncertainty in the formation property model, the Monte Carlo dropout technique may also be used to quantify uncertainty in the predicted formation properties. For example, the Monte Carlo dropout technique may include dropping one or more nodes (464) from the model. The Monte Carlo simulation may then provide a plurality of predicted formation properties based on the one or more nodes that have been dropped from the model. A mean and standard deviation of the predicted formation properties may be calculated based on the plurality of predictions which will provide the quantitative uncertainty of the predicted formation properties.

FIG. 5 shows an example representation of resistivity profile 500 generated with a formation property prediction model, according to some implementations. For example, the formation property prediction model may be the Neural Network model pretrained by the neural network training unit 218 of FIG. 2 and uploaded to the formation property prediction model unit 220. The first graph 560 represents a one-dimensional resistivity calculated with a pretrained formation property prediction model, such as the formation property prediction model pretrained by the neural network training unit 218 of FIG. 2 or the neural network 400 of FIG. 4. The resistivity of the formation is provided as a heat map, with higher resistivity shown as darker color and lower resistivity as lighter color. The second graph 562 represents uncertainty of the resistivity model. The uncertainty may be calculated in any manner, including utilizing the Monte Carlo Dropout technique described herein. Darker colors represent higher uncertainty while lighter colors represent lower uncertainty. As can be seen from the second graph 562, uncertainty generally increases the further away the predictions reach from the wellbore 564. Furthermore, the two graphs show a correlation between the predicted resistivity and uncertainty.

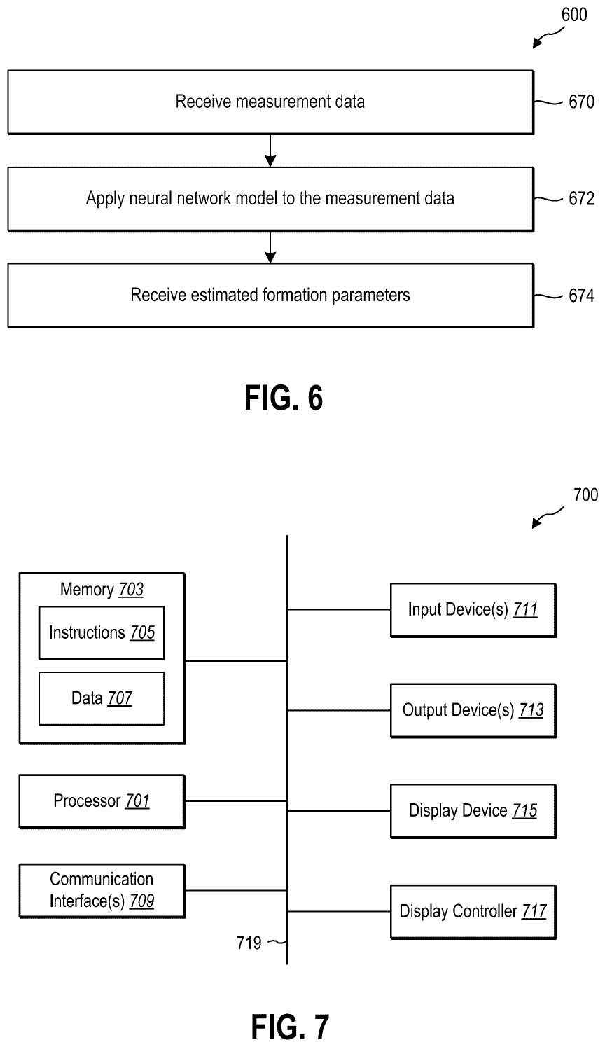

FIG. 6 illustrates a flowchart of a method 600 for predicting formation properties, according to an embodiment. The method may include an act 670 of receiving measurement data. For example, the measurement data may be deep directional resistivity (DDR) measurement data from one or more DDR sensors. The method may further include an act 672 of applying a formation property model to the received measurement data. For example, the formation property prediction model may have been pretrained to identify predicted formation parameters based on an input DDR data, formation properties of the input DDR data, and tool parameters. The method may further include an act 674 of receiving predicted formation parameters. For example, the received predicted formation parameters are received in response to applying the formation property prediction model to the DDR measurement data. In some embodiments, the received predicted formation parameters include at least one or more of a resistivity, an anisotropy, a dip of the formation, and an azimuth. While FIG. 6 illustrates acts according to one or more embodiments, alternative embodiments may omit, add to, reorder, and/or modify any of the acts shown in FIG. 6. The acts of FIG. 6 can be performed as part of a method. Alternatively, a system can perform the acts of FIG. 6. In some embodiments, one or more computing devices may perform the acts of FIG. 6.

In some embodiments, any of the methods of the present disclosure may be executed by a computing system. FIG. 7 illustrates an example of such a computing system 700, in accordance with some embodiments. The computing system 700 may include a computer or computer system, which may be an individual computer system or an arrangement of distributed computer systems.

FIG. 7 illustrates certain components that may be included within a computer system 700. One or more computer systems 700 may be used to implement the various devices, components, and systems described herein.

The computer system 700 includes a processor 701. The processor 701 may be a general-purpose single or multi-chip microprocessor (e.g., an Advanced RISC (Reduced Instruction Set Computer) Machine (ARM)), a special purpose microprocessor (e.g., a digital signal processor (DSP)), a microcontroller, a programmable gate array, etc. The processor 701 may be referred to as a central processing unit (CPU). Although just a single processor 701 is shown in the computer system 700 of FIG. 7, in an alternative configuration, a combination of processors (e.g., an ARM and DSP) could be used.

The computer system 700 also includes memory 703 in electronic communication with the processor 701. The memory 703 may be any electronic component capable of storing electronic information. For example, the memory 703 may be embodied as random access memory (RAM), read-only memory (ROM), magnetic disk storage media, optical storage media, flash memory devices in RAM, on-board memory included with the processor, erasable programmable read-only memory (EPROM), electrically erasable programmable read-only memory (EEPROM) memory, registers, and so forth, including combinations thereof.

Instructions 705 and data 707 may be stored in the memory 703. The instructions 705 may be executable by the processor 701 to implement some or all of the functionality disclosed herein. Executing the instructions 705 may involve the use of the data 707 that is stored in the memory 703. Any of the various examples of modules and components described herein may be implemented, partially or wholly, as instructions 705 stored in memory 703 and executed by the processor 701. Any of the various examples of data described herein may be among the data 707 that is stored in memory 703 and used during execution of the instructions 705 by the processor 701.

A computer system 700 may also include one or more communication interfaces 709 for communicating with other electronic devices. The communication interface(s) 709 may be based on wired communication technology, wireless communication technology, or both. Some examples of communication interfaces 709 include a Universal Serial Bus (USB), an Ethernet adapter, a wireless adapter that operates in accordance with an Institute of Electrical and Electronics Engineers (IEEE) 802.11 wireless communication protocol, a Bluetooth® wireless communication adapter, and an infrared (IR) communication port.

A computer system 700 may also include one or more input devices 711 and one or more output devices 713. Some examples of input devices 711 include a keyboard, mouse, microphone, remote control device, button, joystick, trackball, touchpad, and lightpen. Some examples of output devices 713 include a speaker and a printer. One specific type of output device that is typically included in a computer system 700 is a display device 715. Display devices 715 used with embodiments disclosed herein may utilize any suitable image projection technology, such as liquid crystal display (LCD), light-emitting diode (LED), gas plasma, electroluminescence, or the like. A display controller 717 may also be provided, for converting data 707 stored in the memory 703 into text, graphics, and/or moving images (as appropriate) shown on the display device 715.

The various components of the computer system 700 may be coupled together by one or more buses, which may include a power bus, a control signal bus, a status signal bus, a data bus, etc. For the sake of clarity, the various buses are illustrated in FIG. 7 as a bus system 719.

In the foregoing specification, the invention has been described with reference to specific example implementations thereof. Various implementations and aspects of the invention(s) are described with reference to details discussed herein, and the accompanying drawings illustrate the various implementations. The description above and drawings are illustrative of the invention and are not to be construed as limiting the invention. Numerous specific details are described to provide a thorough understanding of various implementations of the present invention.

The present invention may be embodied in other specific forms without departing from its spirit or essential characteristics. The described implementations are to be considered in all respects only as illustrative and not restrictive. For example, the methods described herein may be performed with less or more steps/acts or the steps/acts may be performed in differing orders. Additionally, the steps/acts described herein may be repeated or performed in parallel to one another or in parallel to different instances of the same or similar steps/acts. The scope of the invention is, therefore, indicated by the appended claims rather than by the foregoing description. All changes that come within the meaning and range of equivalency of the claims are to be embraced within their scope.

It should be appreciated that computing system 700 is only one example of a computing system, and that computing system 700 may have more or fewer components than shown, may combine additional components not depicted in the example embodiment of FIG. 7, and/or computing system 700 may have a different configuration or arrangement of the components depicted in FIG. 7. The various components shown in FIG. 7 may be implemented in hardware, software, or a combination of both hardware and software, including one or more signal processing and/or application specific integrated circuits.

Embodiments of the present disclosure may thus utilize a special purpose or general-purpose computing system including computer hardware, such as, for example, one or more processors and system memory. Embodiments within the scope of the present disclosure also include physical and other computer-readable media for carrying or storing computer-executable instructions and/or data structures, including applications, tables, data, libraries, or other modules used to execute particular functions or direct selection or execution of other modules. Such computer-readable media can be any available media that can be accessed by a general purpose or special purpose computer system. Computer-readable media that store computer-executable instructions (or software instructions) are physical storage media. Computer-readable media that carry computer-executable instructions are transmission media. Thus, by way of example, and not limitation, embodiments of the present disclosure can include at least two distinctly different kinds of computer-readable media, namely physical storage media or transmission media. Combinations of physical storage media and transmission media should also be included within the scope of computer-readable media.

Both physical storage media and transmission media may be used temporarily store or carry, software instructions in the form of computer readable program code that allows performance of embodiments of the present disclosure. Physical storage media may further be used to persistently or permanently store such software instructions. Examples of physical storage media include physical memory (e.g., RAM, ROM, EPROM, EEPROM, etc.), optical disk storage (e.g., CD, DVD, HDDVD, Blu-ray, etc.), storage devices (e.g., magnetic disk storage, tape storage, diskette, etc.), flash or other solid-state storage or memory, or any other non-transmission medium which can be used to store program code in the form of computer-executable instructions or data structures and which can be accessed by a general purpose or special purpose computer, whether such program code is stored as or in software, hardware, firmware, or combinations thereof.

A “network” or “communications network” may generally be defined as one or more data links that enable the transport of electronic data between computer systems and/or modules, engines, and/or other electronic devices. When information is transferred or provided over a communication network or another communications connection (either hardwired, wireless, or a combination of hardwired or wireless) to a computing device, the computing device properly views the connection as a transmission medium. Transmission media can include a communication network and/or data links, carrier waves, wireless signals, and the like, which can be used to carry desired program or template code means or instructions in the form of computer-executable instructions or data structures and which can be accessed by a general purpose or special purpose computer.

Further, upon reaching various computer system components, program code in the form of computer-executable instructions or data structures can be transferred automatically or manually from transmission media to physical storage media (or vice versa). For example, computer-executable instructions or data structures received over a network or data link can be buffered in memory (e.g., RAM) within a network interface module (NIC), and then eventually transferred to computer system RAM and/or to less volatile physical storage media at a computer system. Thus, it should be understood that physical storage media can be included in computer system components that also (or even primarily) utilize transmission media.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

1. A method for predicting formation properties, comprising:
receiving deep directional resistivity (DDR) measurement data from one or more DDR sensors;
applying a formation property prediction model to the DDR measurement data, the formation property prediction model pretrained to identify predicted formation parameters based on input DDR data, the formation properties of the input DDR data, and tool parameters; and
receiving the predicted formation parameters for a subsurface beyond the wellbore in response to applying the formation property prediction model to the DDR measurement data.

2. The method of claim 1, wherein the predicted formation parameters include at least one or more of a resistivity, an anisotropy, a dip of the formation, and an azimuth.

3. The method of claim 1, wherein the formation property prediction model further includes uncertainty information associated with the formation property prediction model.

4. The method of claim 3, wherein the uncertainty information is epistemic uncertainty that has been calculated using Monte Carlo Dropout technique.

5. The method of claim 1, wherein the method is performed at a bottomhole assembly.

6. The method of claim 2, wherein the formation property prediction model is a pixel based model.

7. The method of claim 6, wherein the predicted formation parameters are calculated for each pixel.

8. The method of claim 2, wherein the formation property prediction model is a layer boundary based model.

9. The method of claim 8, wherein the predicted formation parameters are calculated for the layer boundary based model.

10. The method of claim 1, wherein the tool parameters include one or more of BHA assembly information, BHA trajectory, DDR sensor configuration information.

11. The method of claim 10, wherein the DDR sensor further includes a transmitter and a receiver, for transmitting and receiving electromagnetic frequencies.

12. The method of claim 11, wherein the DDR sensor configuration information includes one or more of a distance between the transmitter and the receiver, and an angle between the transmitter and the receiver.

13. The method of claim 1, wherein the predicted formation parameters are used for making adjustments to drilling in real time or adjusting drilling formation plan.

14. The method of claim 1, wherein the formation property prediction model includes at least one of a convolutional neural network, transformer network, feedforward neural network, residual neural network, recurrent neural network, generative neural network, generative adversarial network, or a single-shot detection network.

15. A system for predicting formation properties, comprising:
a deep directional resistivity (DDR) sensor for measuring deep directional resistivity; and
a model generated by a neural network for identifying predicted formation parameters based on a DDR measurement data measured by the DDR sensor and inputted to the neural network without calculating inversion.

16. The system of claim 15, wherein the DDR sensor and the model are located downhole at a bottomhole assembly.

17. The system of claim 15, wherein the DDR sensor further includes one or more transmitters for transmitting an electromagnetic waves.

18. The system of claim 17, wherein the electromagnetic waves have a frequency range between 2 and 72 kilo Hertz (kHz).

19. The system of claim 15, wherein the predicted formation parameters include at least one or more of a resistivity, anisotropy, and dip of the formation.

20. A system comprising:
a computing device having a processor; and
a computer memory including instructions that, when executed by the computing device, cause the computing device to carry out operations comprising:
receiving deep directional resistivity (DDR) measurement data from one or more DDR sensors;
applying a formation property prediction model to the DDR measurement data, the formation property prediction model pretrained to identify predicted formation parameters based on input DDR data, formation properties of the input DDR data, and tool parameters; and
receiving the predicted formation parameters for a subsurface beyond the wellbore in response to applying the formation property prediction model to the DDR measurement data.
